(19) United States
(12) Patent Application Publication
(10) Pub. No.: US 2023/0326745 A1
(43) Pub. Date: Oct. 12, 2023

(54) METHOD FOR PRODUCING A LAYER ON ONLY CERTAIN SURFACES OF A STRUCTURE

(71) Applicants: COMMISSARIAT A L'ENERGIE ATOMIQUE ET AUX ENERGIES AL TERNATIVES, Paris (FR); UNIVERSITE GRENOBLE ALPES, Saint Martin D'Heres (FR); CENTRE NATIONAL DE LA RECHERCHE SCIENTIFIQUE, Paris (FR)

(72) Inventors: Marceline BONVALOT, Eybens (FR); Christophe VALLEE, Le Touvet (FR); Taguhi YEGHOYAN, Bourgoin-Jallieu (FR); Nicolas POSSEME, Grenoble (FR)

(21) Appl. No.: 18/011,332

(22) PCT Filed: Jun. 18, 2021
(86) PCT No.: PCT/EP2021/066714

§ 371 Date: Dec. 19, 2022

(30) Foreign Application Priority Data
Jun. 19, 2020 (FR) FR2006444

(51) Int. Cl. H01L 21/311; H01L 21/02

(52) U.S. Cl. CPC H01L 21/0228; H01L 21/02208; H01L 21/02274; H01L 21/0234; H01L 21/31122; H01L 21/31144

(57) ABSTRACT

A method for producing a layer covering the first surfaces of a structure and leaving the second surfaces uncovered including a sequence for forming an initial layer by PEALD deposition, the sequence including cycles, each including injections of first and second precursor in a reaction chamber, and plasma formation in the reaction chamber. The cycles are carried out at a temperature T_{cycle} such that T_{cycle} ≤ (Tₘᵢₙ - 20° C.), Tₘᵢₙ being the minimum temperature of a nominal temperature window for a PEALD deposition. The method includes exposing the initial layer to a densification plasma such that the exposure to the ion flow makes the material on the first surfaces more resistant to etching than the material on the second surfaces. The method also includes a selective etching step, such that the initial layer covers the first surfaces of the front face of the structure by leaving the second surfaces uncovered.

### TECHNICAL FIELD

The present invention relates to a microelectronic method for producing a layer only on certain surfaces of a structure. The invention has numerous applications in the field of microelectronics. It can, for example, be implemented for producing etching masks. It will also be advantageous for producing transistors by implementing manufacturing methods with sacrificial gates (usually qualified as gate-last methods).

### STATE OF THE ART

For numerous applications, it is useful to form a layer only on certain surfaces of a substrate having a surface topology. FIG. 1A illustrates an example of a substrate 100, the topology of which forms grooves 101 or trenches. This substrate 100 thus has horizontal surfaces 110 located on the top 111 and in the bottom 112 of the grooves 101. It also has vertical surfaces 120 on the walls of the grooves 101. It can be useful to form a layer 200 on the horizontal surfaces 110 only, and by leaving the vertical surfaces 120 uncovered, as illustrated in FIG. 2.

Known solutions for achieving this consist of carrying out the following steps:
depositing a solid plate layer, i.e. on all the surfaces of the front face of the substrate.
carrying out conventional lithography steps for removing the layer deposited on the vertical surfaces, while preserving the layer on the horizontal surfaces.

The result of the solid plate deposition step is illustrated in FIG. 1B. The layer 200, deposited in a conform manner has regions 210, 211, 212 surmounting the horizontal surfaces 110, 111, 112 and regions 220 surmounting the vertical surfaces 120. This deposition step can, for example, be carried out by atomic layer deposition (ALD), optionally plasma-enhanced atomic layer deposition (PEALD). ALD techniques are based on a self-limiting growth method, wherein the material is deposited layer-by-layer. It is thus possible to design films on a nanometric scale with a good conformity. Generally, the ALD technique consists of sequentially injecting into the reaction chamber of a reactor, a first precursor of a first reagent, then a second precursor of a second reagent. The first gaseous precursor is metallic, metalloid or lanthanide which does not react with itself. The second gaseous reagent reacts with the first adsorbed reagent to enable the reactivation of the adsorption of the first precursor during the following alternance.

FIG. 3 illustrates different steps of an example of an ALD deposition cycle 1. A first step 10 consists of injecting the first reagent which reacts by chemisorption with the uncovered surface of the substrate. Then, a purging step 20 is carried out to remove the portion of the first reagent not having reacted, as well as the reactional products. In the step 30, the second reagent is injected, which reacts by chemisorption with the first adsorbed reagent. Then, a purging step 40 is carried out to remove the second reagents not having reacted, as well as the reactional products.

In a PEALD method, the second reagent is generated by a plasma. The step 30 thus comprises a step 31 of injecting the second reagent and of stabilising species in presence, then a step 32 of forming a plasma. To obtain a desired thickness layer, this cycle 1 is repeated as many times as necessary. In FIG. 3, the dotted arrow and the number N illustrate this iterative character and the number of cycles carried out.

After having proceeded with the deposition, the lithography techniques comprise numerous steps for forming one or more masks, ultimately making it possible to conceal the horizontal surfaces and to expose the vertical surfaces. The layer to be produced is then etched through the mask to remove the regions 220 located on the vertical surfaces 120 of the substrate, while preserving the regions 210, 211, 212 of layer 200 covering the horizontal surfaces 110, 111, 112. Thus, the result illustrated in FIG. 2 is obtained. These known solutions have the disadvantage of requiring numerous steps, in particular for producing and positioning different masks. Moreover, they have a limited accuracy due to inevitable errors and alignment tolerance of the different masks. These solutions are therefore long and expensive to implement.

There is therefore a need, consisting of proposing a solution to reduce the disadvantages of the known solutions.

An aim of the present invention consists of responding to at least one of these needs. In particular, an aim of the present invention consists of proposing a solution to improve the accuracy of the known solutions.

### SUMMARY

To achieve this aim, according to an embodiment, a method is provided for producing a layer covering the first surfaces of a front face of a structure and leaving the second surfaces of this front face uncovered, the first surfaces and the second surfaces having different inclines, the method comprising at least:
a sequence of forming an initial layer by plasma-enhanced atomic layer deposition (PEALD) on the front face of the structure, the sequence comprising a plurality of cycles, each cycle comprising at least:
   an injection of a first precursor in a reaction chamber of a reactor containing the structure,
   an injection of a second precursor in the reaction chamber and the formation in the reaction chamber of a plasma, called deposition plasma, so as to form at each cycle, on said first and second surfaces of the structure, a film forming a portion of said initial layer.

The cycles are carried out at a temperature T_{cycle} such that T_{cycle}≤(Tₘᵢₙ-20° C.), Tₘᵢₙ being the minimum temperature of a nominal window (F_{T}) of temperatures for a PEALD deposition from the first and second precursors.

The method comprises at least one step of exposing the initial layer, formed or undergoing formation by PEALD to a plasma, called densification plasma, during which a non-zero polarisation is applied to the structure, so as to give a favoured direction to an ion flow generated by the densification plasma. This favoured direction being oriented such that at least one superficial portion of the initial layer, deposited or undergoing formation by PEALD, has:
o first regions, covering the first surfaces of the structure and which are exposed to the ion flow of the densification plasma,
o second regions, covering the second surfaces of the structure and which are not exposed to the ion flow of the densification plasma.

Preferably, the densification plasma, at least the polarisation, is configured such that the exposure to the ion flow of the densification plasma makes the material of the first regions more resistant to etching than the material. Typically, the polarisation is configured such that the exposure to the ion flow of the densification plasma confers to the material of the first regions, a density greater than the density of the material of the second regions and/or an impurity rate less than an impurity rate of the material of the second regions. Thanks to this control of the polarisation of the substrate, the energy of the ions which arrive on the exposed surface of the substrate is partially controlled, which makes it possible to densify it.

The application of a polarisation voltage V_{bias} __{substrat} at the substrate makes it possible to increase the energy of the ions of the plasma in a controlled manner and independent from the voltage Vₚₗₐₛₘₐ induced by the source used to generate the nitrogen-based plasma. The effectiveness of the plasma treatment can thus be modulated in a controlled manner to further improve the properties of the interface obtained. The electrical performances of the component are consequently improved.

The method also comprises, coming from the step of exposing the initial layer, formed or undergoing formation by PEALD, to the densification plasma, at least one step of selectively etching the second regions vis-à-vis the first regions. Thus, after etching, the initial layer covers the first surfaces of the front face of the structure by leaving the second surfaces uncovered.

Thus, the method proposed provides carrying out PEALD cycles at a temperature less than the temperature of the nominal window. The resulting deposition of these cycles therefore has a deteriorated quality with respect to a deposition carried out in the nominal window.

Moreover, the densification plasma enhanced by a polarisation of the substrate is oriented so as to only expose the first surfaces of the substrate, which makes it possible to cover the latter by a thin layer portion which has a very good quality. A significant improvement of the chemical purity is observed, of the stoichiometry and of the density of the layer deposited in these regions exposed to the plasma with polarisation, in an unexpected measure. The layer deposited by PEALD therefore has:
a very good quality superficial film covering the first surfaces of the structure,
a degraded quality superficial film covering the second surfaces of the structure.

The second surfaces are thus more sensitive to etching, enabling their removal while preserving the good quality superficial film on the first surfaces.

The method proposed thus enables a selective deposition only on certain surfaces of the substrate, without needing to resort to conventional lithography techniques, involving the successive positioning of masks.

Consequently, the method proposed makes it possible to considerably improve the accuracy of the patterns of this layer selectively deposited only on certain surfaces of the substrate. Moreover, it makes it possible to reduce the duration and the cost with respect to the methods requiring subsequent lithography steps. This method, for example, makes it possible to achieve with a very good accuracy of the etching masks.

Carrying out a PEALD deposition at a temperature less than the low temperature of the recommended window, function of the nature of the precursor, is a process totally contrary to all good practices of PEALD techniques.

Moreover, the combination of this low-temperature PEALD deposition with one or more steps of applying a plasma with polarisation has made it possible to observe, in the end:
a degradation, in a fully unexpected measure, of the density of the material deposited at low temperature,
an improvement, also in a fully unexpected measure, of the density of the material deposited when the latter is deposited under the same low-temperature conditions, but with the addition of a polarisation.

Ultimately, it is this very large difference in density of the material on surfaces having different orientations which makes it possible to obtain a selective deposition only on certain surfaces (typically, the horizontal surfaces).

Furthermore, the method proposed makes it possible to deposit very varied materials to form a nitride-, sulphur oxide-based layer. Known PEALD solutions do not make it possible to deposit also varied materials, selectively on certain surfaces and with a satisfactory quality of layer obtained. Such is, for example, the case of the HFO₂ deposition.

### BRIEF DESCRIPTION OF THE FIGURES

The aims, objectives, as well as the features and advantages of the invention will emerge best from the detailed description of an embodiment of the latter, which is illustrated by the following accompanying drawings, wherein:

FIGS. 1A and 1B illustrate a 3D substrate-type starting structure, and an intermediate structure making it possible to obtain a desired structure illustrated in FIG. 2.

FIG. 1B illustrates the conform deposition obtained on a 3D starting structure.

FIG. 2 illustrates an example of a final structure obtained after implementation of the method according to the invention. Only the horizontal surfaces are covered, while the vertical surfaces are uncovered.

FIG. 3 schematically represents a conventional cycle of a PEALD deposition.

FIG. 4 is a graph illustrating the nominal temperature window to be applied to a PEALD cycle to obtain a satisfactory growth in terms of quality of the layer obtained (stoichiometry, density and chemical purity). This graph also illustrates the damaging consequences on the growth when the temperature applied to the PEALD cycle is outside of this nominal window.

FIG. 5 schematically represents a method according to an example of an embodiment of the present invention.

FIG. 6 schematically illustrates the structure obtained after having repeated several cycles illustrated in FIG. 5, and before the selective etching step.

FIG. 7 schematically represents a method according to a second example of an embodiment of the present invention. This figure shows that this method comprises a first sequence of PEALD cycles without polarisation voltage applied to the substrate, then a second sequence of PEALD cycles with polarisation voltage applied to the substrate, in order to densify the surface portion of the deposited layer.

FIG. 8 schematically illustrates the structure obtained after implementation of the cycles illustrated in FIG. 7, and before the selective etching step.

FIG. 9 schematically represents a method according to a third example of an embodiment of the present invention.

FIG. 10 schematically represents a variant of an embodiment, wherein a structure is inclined with respect to an ion flow generated by a plasma.

FIG. 11 illustrates a diagram of an example of a plasma reactor which can be used to implement the invention.

The drawings are given as examples and are not limiting of the invention. They constitute principle schematic representations intended to facilitate the understanding of the invention and are not necessarily to the scale of practical applications. In particular, the thickness of the different layers and films are not representative of reality.

### DETAILED DESCRIPTION

Before starting a detailed review of embodiments of the invention, optional features are stated below which can optionally be used in association or alternatively:

According to an example, the step of exposing the initial layer to the densification plasma is carried out at each cycle of the sequence of forming the initial layer by PEALD, the deposition plasma being the densification plasma.

Thus, the portion densified by the plasma extends over the whole thickness of the initial layer. This embodiment has the advantage of forming a very good quality layer on the first surfaces while facilitating the removal of the layer deposited on the second surfaces. The performances of the device integrating this layer are therefore improved.

According to an example, the step of exposing the initial layer to the densification plasma is carried out only during N_{B} last cycles of the sequence of forming the initial layer by PEALD, the deposition plasma being the densification plasma during these N_{B} last cycles, the total number of cycles of the sequence is equal to N_{A}+N_{B}, N_{A} and N_{B} being non-zero integers. According to an example, N_{B} =1.

Thus, the film densified by the plasma extends over only one portion of the thickness of the initial layer. This densified film extends from the free face of the layer and therefore covers the latter. It does not extend over the whole thickness of the layer deposited by PEALD. This embodiment has the advantage of forming a good quality layer on the first surfaces while facilitating the removal of the layer deposited on the second surfaces.

According to an example, the method comprises a plurality of sequences, each sequence comprising N_{B} steps of exposing the initial layer to the densification plasma. Thus, according to this embodiment, PEALD cycles are alternated without polarisation and N_{B} cycles with polarisation. Preferably at each sequence, only one step of exposing to the densification plasma (N_{B}=1) is carried out.

According to an example, the step of exposing the initial layer to the densification plasma is only carried out after the sequence of forming the initial layer by PEALD.

The densification plasma can be applied in a reactor different from that used to carry out the PEALD cycles without polarisation. The densification plasma therefore leads to the formation of a film on the initial layer already formed by PEALD. This embodiment has the advantage of being able to be achieved ex situ, for example in a CCP etching reactor (capacitive coupling plasma reactor). Therefore, this embodiment can therefore be implemented when no polarisation kit is not installed indwelling on the PEALD reactor. This embodiment therefore involves less constraints on the necessary equipment.

According to an alternative example, the reactor used is of the ICP (inductive coupling plasma reactor) type. All the steps of the method can be carried out in this reactor. Steps with application of the polarisation voltage to the substrate (V_{bias_substrat} ≠0) can be carried out within the same reactor, and other steps without application of the polarisation voltage to the substrate (V_{bias}__{substrat} =0) can be carried out. All the steps of the PEALD deposition can therefore be carried out within the same reactor, which has considerable advantages in terms of productivity, reproducibility and quality.

According to an example, the method comprises a plurality of sequences, each sequence comprising N_{A} PEALD deposition steps, preferably without polarisation, then these sequences are followed by a step of exposing the initial layer to the densification plasma. Thus, according to this embodiment, PEALD cycles without polarisation and at least one step of exposing to a plasma with polarisation are alternated.

According to an example, which the cycles are carried out at a temperature T_{cycle} less than 100° C., preferably less than 80° C., preferably less than 50° C. According to an example, the cycles are carried out at a temperature T_{cycle} equal to ambient temperature. Thus, the reactor is not heated by a heating device during the implementation of the method. These temperatures make it possible to reinforce further the effectiveness of the method by facilitating the removal of the layer covering the second surfaces of the front face of the structure. The use of temperatures as low is fully counterintuitive for a person skilled in the art.

According to an example, the cycles are carried out at a temperature T_{cycle} such that: T_{cycle}≤(Tₘᵢₙ- 50° C.), preferably T_{cycle}≤(Tₘᵢₙ- 100° C.). For example, T_{cycle} can be less than or equal to 80° C., preferably less than or equal to 70° C., and preferably less than or equal to 50° C. This means that the reactor wherein the steps of the method are implemented is not heated by heating means. According to an example, T_{cycle} is equal to ambient temperature. T_{cycle} and Tₘᵢₙ are in degrees Celsius (°C).

Tₘᵢₙ is the minimum temperature of the ALD or PEALD window, from which the reaction between the precursor, typically the first precursor, and the substrate is sufficiently thermally activated, such that the adsorption reaction can occur in a self-limited manner (and therefore with a constant GPC).

The nominal temperature window F_{T} corresponds to the temperature window recommended to carry out a PEALD deposition from the first and second precursors. This window is typically recommended by the manufacturer of the first precursor. This nominal temperature window is a fully usual parameter is known by a person skilled in the art. In the nominal temperature window, the thickness of the film deposited at each PEALD cycle does not vary or does not substantially vary according to the temperature. Thus, the nominal window is such that by making the PEALD deposition temperatures taken in the nominal window vary, the thickness of the film deposited by PEALD cycle remains constant. More specifically, it remains almost constant. This means that if inside the nominal window, the deposition temperature T_{cycle} of 10° C. is made to vary, the variation in the thickness of the film deposited will be less than or equal to 2%, even less than or equal to 1%.

When the temperature remains less (respectively greater) than the limit Tₘᵢₙ (respectively Tₘₐₓ) of the nominal window, then the thickness of the film deposited by PEALD cycle varies significantly according to the temperature.

For example, outside of the nominal window, a variation in temperature by a few degrees, for example by 10° C. leads to a variation greater than 5% of the thickness deposited at each cycle. For example, outside of the nominal window, a variation in temperature by at least 10° C. leads to a variation greater than 5% of the thickness deposited at each cycle.

The nominal window F_{T} can also be defined as being the temperature interval, inside which the growth is achieved under self-limited reaction conditions. Thus, the nominal window F_{T} can also be defined as corresponding to the temperature interval, for which use of the precursor is made layer-by-layer by a self-limited reaction. Outside of this nominal window, this self-limiting character is not verified.

The minimum width (Tₘₐₓ-Tₘᵢₙ) of the nominal window is preferably greater than 10° C., preferably greater than 20° C. Most often, this window has a width greater than 100° C., even 200 degrees. The width of this window however varies according to the precursors used. A person skilled in the art fully knows how to identify, for a given precursor, the nominal window as well as its limits.

The minimum width of the nominal window is preferably greater than 10° C. and preferably greater than 20° C. Most often, this window has a width greater than 100° C., even 200 degrees. The width of this window however varies according to the precursors used. A person skilled in the art fully knows how to identify, for a given precursor, the nominal window as well as its limits.

According to an example, the width L = Tₘₐₓ-Tₘᵢₙ of the nominal window F_{T} is greater than or equal to 10° C., preferably greater than or equal to 20° C.

According to an example, the width L = Tₘₐₓ-Tₘᵢₙ of the nominal window F_{T} is greater than or equal to 100° C. and preferably greater than or equal to 200 degrees.

According to an example, during the formation of the densification plasma, the pressure of the reaction chamber is less than or equal to 80 mTorr and preferably around 10 mTorr. This makes it possible to ensure a non-collisional sheath in the vicinity of the substrate and therefore to give an anisotropic character to the densification of the superficial film.

According to an example, the polarisation is applied with a polarisation power P_{bias}__{substrat} less than or equal to 150 Watts and with preferably P_{bias} of between 10 W and 120 W. Preferably, P_{bias-substrat} is between 10 Watts and 90 W. This makes it possible to avoid the creation of defects caused by an ion bombardment which is too sudden (in dose and/or in energy). According to an example, the polarisation voltage V_{bias} _{substrat} is applied with a polarisation power less than 150 W, and preferably of between 10 and 120 W, (Watts) corresponding to a polarisation voltage | V_{bias} _{substrat} | less than or equal to 300 Volts and preferably between 10 Volts and 150 Volts.

For example, the deposition of HfO2 (hafnium oxide) requires a low power to avoid its spraying. Typically, it is necessary that P_{bias-substrat} is less than or equal to 80 W. Preferably, P_{bias-substrat} = 20 W for Hf02. The independent control of V_{substrat} and Vₚₗₐₛₘₐ makes it possible to apply a low voltage to the substrate 100 and therefore to accurately control the energy from the ions reaching the layer to be densified. To produce this layer, for example, molybdenum (IV)-amide precursors can be used.

Thus, and generally, the method proposed can be applied to deposit very varied materials. The invention thus proposes a solution to obtain nitride, oxide or sulfide layers from very varied materials. The invention thus makes it possible to remove numerous constraints based on the choice of materials.

According to an example, the total number N of cycles is preferably greater than or equal to 15 and preferably greater than or equal to 20.

According to an example, the first regions exposed to the densification plasma and the second regions not exposed to the densification plasma, different by at least one of the following parameters: a density of the film, and an impurity rate.

According to an example, at least certain and preferably all the first and second surfaces together form a right angle.

According to an example, at least certain and preferably all the first and second surfaces do not together form a right angle. According to an example, a rear face of the structure extends into a plane, the perpendicular to this plane being inclined, preferably by more than 10°, with respect to the favour direction of the ion flow.

According to an example, the layer is on the basis of at least one material which can be deposited by (PEALD).

According to an example, the initial layer is made or is on the basis of a nitride, an oxide or a sulfide.

According to an example, the initial layer is made or is on the basis of a nitride or an oxide obtained from metalorganic or organosilicon or halogenated precursors. According to an example, the first precursor comprises one of the following materials: aluminium (Al), titanium (Ti), tantalum (Ta), silicon (Si), hafnium (Hf), zirconium (Zr), copper (Cu), ruthenium (Ru), lanthanum (La), yttrium (Y).

It is specified that, in the scope of the present invention, the terms “on”, “surmounts”, “covers”, “underlying”, “vis-à-vis” and their equivalents do not necessarily mean “in contact with”. Thus, for example, the deposition, the formation of a layer or of a film on a surface, does not compulsorily mean that the layer or the film are directly in contact with the surface, but means that they cover at least partially the surface, either by being directly in contact with it, or by being separated from it, for example, by at least one other layer or one other film.

By a species A-“based“ substrate, film, layer, gaseous mixture, plasma, this means a substrate, a film, a layer, a gaseous mixture, a plasma comprising this species A only or this species A and optionally other species.

The substrate comprises at least one structure, a front face of which is exposed to the species present in the reaction chamber of the reactor. The structure is thus supported by the substrate or is formed on the substrate. It can also be provided that the structure is the substrate. These two terms thus have the same meaning.

Several embodiments of the invention implementing successive steps of the manufacturing method are described below. Except explicitly mentioned, the adjective “successive” does not necessarily imply, even if this is generally preferred, that the steps follow one another immediately, intermediate steps could separate them.

Moreover, the term “step” means the embodiment of a part of the method, and can mean a set of sub-steps.

Moreover, the term “step” does not compulsorily mean that the actions carried out during a step are simultaneous or immediately successive. Certain actions of a first step can in particular be following by actions linked to a different step, and other actions of the first step can then be resumed. Thus, the term “step” does not necessarily mean single and inseparable actions over time and in the sequence of phases of the method.

The word “dielectric” qualifies a material of which the electrical conductivity is sufficiently low in the given application to serve as an insulator. In the present invention, a dielectric material preferably has a dielectric constant greater than 4. The spacers are typically formed of a dielectric material.

In the present patent application, when a gaseous mixture is expressed with percentages, these percentages correspond to fractions of the total flow rate of the gases injected in the reactor. Thus, if a gaseous mixture, for example intended to form a plasma, comprises x% of the gas A, this means that the injection flow rate of the gas A corresponds to x% of the total flow rate of the gases injected in the reactor to form the plasma.

By microelectronic device, this means any type of device produced with microelectronic means. These devices comprise, in particular, in addition to purely electronic purpose devices, micromechanical or electromechanical devices (MEMS, NEMS, etc.), as well as optical or optoelectronic devices (MOEMS, etc.).

This can be a device intended to ensure an electronic, optical, mechanical function, etc. It can also be an intermediate product only intended to produce another microelectronic device.

It is specified that, in the scope of the present invention, the thickness of a layer or of the substrate is measured in a direction perpendicular to the surface, according to which this layer or this substrate has its maximum extension. The thickness is thus taken in a direction perpendicular to the main faces of the substrate on which the different layers rest.

The terms “substantially”, “about”, “around” mean “close to 10%”.

Before describing different embodiments of the present invention, the impact of the temperature during a PEALD cycle will now be presented in reference to FIG. 4.

The parameters of each PEALD deposition must be adapted according in particular to the nature of the precursors used.

These parameters are adjusted according to accessible experimental parameters: flows of precursors in the chamber (caused by an inert gas flow), opening time of the injection of precursors, purging time, duration of the plasma step, operating pressure, temperature of the precursor before its injection in the chamber of the reactor (its temperature must be located in its stability zone in the gaseous state) and deposition temperature.

The latter parameter, the deposition temperature, is particularly critical for obtaining a layer of good physical and chemical quality. It corresponds to the temperature at which the substrate is maintained during the PEALD cycle.

For given precursors, the nominal temperature window is available from the supplier of the first precursor. This nominal window corresponds to the temperature interval inside which the growth is achieved under self-limited reaction conditions. More specifically, the depositions show a very good conformity, with a very good control of the thickness of the growing thin layer.

This nominal window is, for example, given by the manufacturer of the precursor. This nominal window can be validated by a person skilled in the art, typically the process engineer responsible for the development of experimental parameters on a determined ALD or PEALD reactor.

This nominal window F_{T} is illustrated in FIG. 4. The lower and upper limits of this window F_{T} are referenced Tₘᵢₙ and Tₘₐₓ on the abscissa axis. The ordinate axis corresponds to the deposition rate, more specifically to the growth thickness per ALD or PEALD cycle. This growth thickness per cycle is usually referenced GPC (growth per cycle). As this appears clearly in FIG. 4, by making the temperatures of the cycle T_{cycle} vary, while preserving these temperatures inside the window F_{T}, then the GPC remains fully stable.

If, on the contrary, the deposition temperature is less than the lower limit Tₘᵢₙ of the window F_{T}, then the precursor is condensed on the surface of the substrate (leading to an artificial increase of the GPC), instead of being chemisorbed (in a self-limited manner). Several layers of precursor molecules can be physisorbed on the substrate by being stacked on top of one another. The physisorption is indeed not self-limited and a greater deposition rate is thus observed. This scenario corresponds to the region 41 of FIG. 4.

Alternatively, always in the case of deposition temperatures less than the lower limit Tₘᵢₙ of the window F_{T}, the physisorption cannot occur in the case where the thermal energy is not sufficient. This minimum thermal energy is a function of the nature of the precursor and of the substrate. If this temperature is too low such that the surface reactions occurred, then no film growth is observed. This scenario corresponds to the region 42 of FIG. 4.

Thus, the nominal window F_{T} is such that by making the PEALD deposition temperature vary, for temperatures taken below the nominal window F_{T}, the thickness of the film deposited at each PEALD cycle varies. For example, by making the temperature T_{cycle} vary by more than 10° C. below Tₘᵢₙ, the thickness of the film deposited at each PEALD cycle varies by more than 5%, even by more than 10%. While the temperature T_{cycle} is made to vary by more than 10° C. inside the nominal window F_{T}, the thickness of the film deposited at each PEALD cycle does not vary or not by more than 2%, even not by more than 1%.

The regions 43 and 44 correspond to situations wherein the deposition temperature is greater than the maximum temperature Tₘₐₓ of the window F_{T}. In this case, the precursor can be broken down and the deposition method becomes of the chemical vapour deposition (CVD or pseudo-CVD) type with the film growth, which is a lot quicker, caused by the loss of the self-limited character of the reaction. This scenario corresponds to the region 43 of FIG. 4.

The high temperature can also activate the desorption of the chemisorbed precursor and leads to a drop in the GPC (region 44 of FIG. 4). Most often, these two phenomena (breaking down of the precursor 43 and activation of the desorption 44) are competitive and simultaneous.

Thus, the nominal window F_{T} is such that my making the PEALD deposition temperature vary, for temperature taken above the nominal window F_{T}, the thickness of the film deposited at each PEALD cycle varies. For example, by making the temperature T_{cycle} vary by at least 10° C. above Tₘₐₓ, the thickness of the film deposited at each PEALD cycle varies by more than 5%, even more than 10%, even more than 20%.

The minimum width of the nominal window is preferably greater than 10° C., preferably greater than 20° C. Most often, this window has a width greater than 100° C., even 200 degrees. The width of this window however varies according to the precursors used. A person skilled in the art knows fully how to identify, for a given precursor, the nominal window, as well as its limits.

In PEALD mode, the temperature window is wider than in ALD mode, and most often extended towards the low temperatures than in ALD. The process engineer responsible for the development of the experimental parameters knows how to determine this window in ALD or PEALD mode.

The deposited layer is on the basis of at least one material which can be deposited by (PEALD). Typically, this is a layer made or is nitride-, oxide- or sulfide-based.

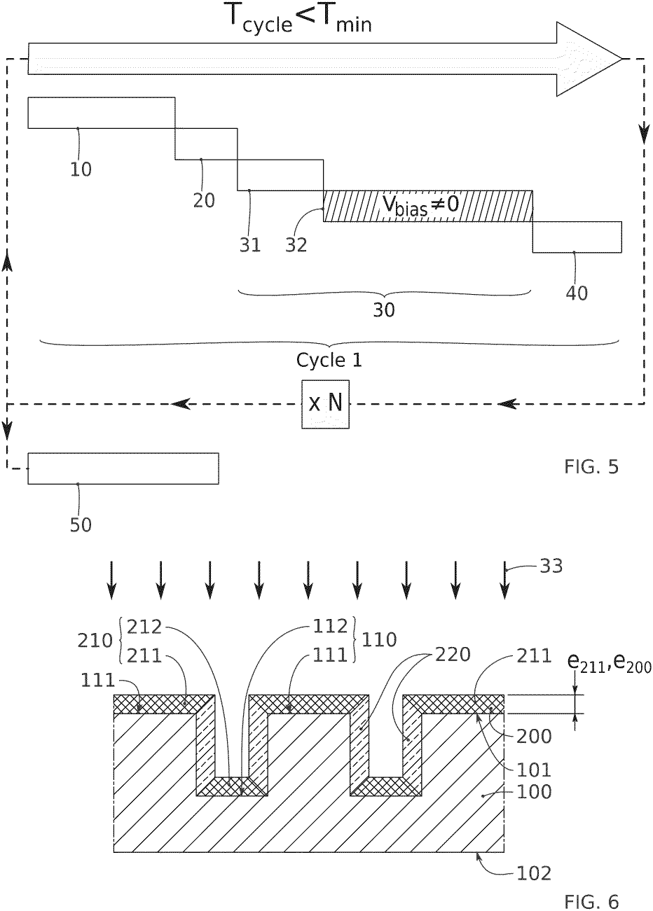

The invention will now be described in detail in reference to several embodiments illustrated in FIGS. 5 to 10.

### Embodiment Illustrated in FIGS. 5 and 6

A first example of a method according to the invention will now be described in reference to FIGS. 5 and 6. FIG. 5 illustrates, schematically, the main steps of this embodiment.

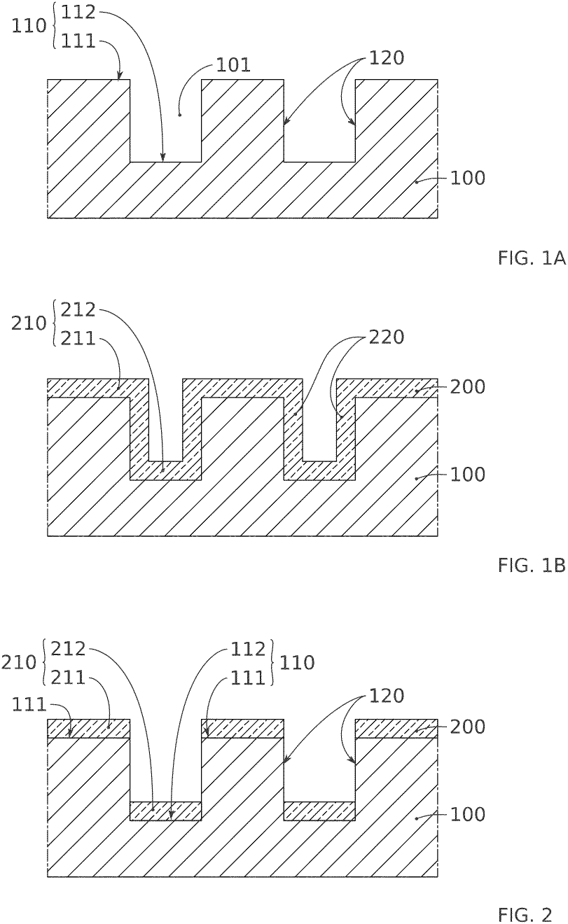

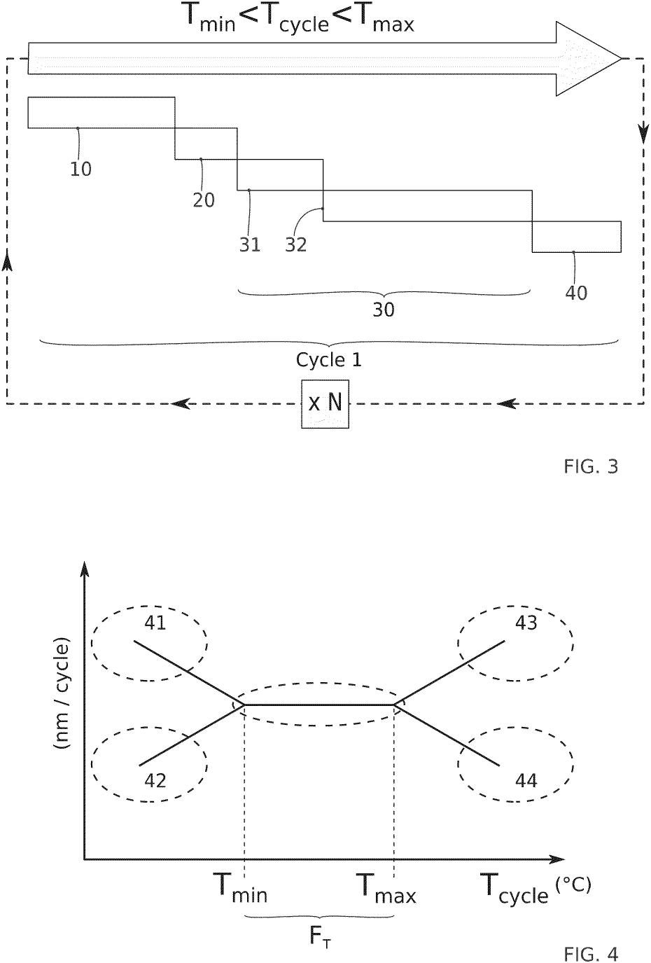

FIGS. 1A and 2 described above correspond respectively to an example of a starting substrate and to a structure that is sought to be obtained in the end. FIG. 6 illustrates the intermediate result obtained before a selective etching step.

As illustrated in FIG. 5, the method comprises a sequence comprising an iteration of N cycles 1.

Each cycle 1 comprises at least the following steps:

A first step comprises the injection 10 in the reaction chamber of the reactor of a first precursor. This first precursor is taken from among the metal, metalloid or lanthanide precursors. This precursor can be on the basis of one of the following materials: aluminium (Al), titanium (Ti), tantalum (Ta), silicon (Si), hafnium (Hf), zirconium (Zr), copper (Cu), ruthenium (Ru), lanthanum (La), yttrium (Y).

A second step is a purging step 20. This purging 20 is carried out to remove the excess of the first precursor, i.e. to discharge the reagents from the first precursor which have not reacted, as well as the reactional products. During this purging, preferably a neutral scavenging gas such as argon (Ar) or dinitrogen (N₂) is injected into the reaction chamber.

A third step 30 comprises an injection 31 into the reaction chamber of a second precursor and a pressure stabilisation step, as well as a plasma formation step 32. This second precursor can be, for example, a plasma generated in an oxygen-based atmosphere for the growth of oxides, nitrogen and/or hydrogen or ammonia (NH₃) for the growth of nitrides, or sulfides. For sulfides, the first precursors 1 already contain sulfide atoms, and the second precursor is a reducer (H₂ or NH₃ in ALD or PEALD).

A fourth step is a purging step 40. This purging 40 is carried out to remove the excess of the second precursor, as well as the reactional products.

The solid arrow gives an indication, only as an example, of relative durations of the cycle and of each of these steps 10 to 40.

It will be noted that the first step and the third step can be inverted by each being accompanied by a purging step. Thus, in an alternative, which is illustrated in FIG. 5, the method can be implemented over the following chronology: 30, 40, 10, 20. In this particular case, the first plasma step 30 serves to activate the surface of the substrate to facilitate the adhesion of the metal precursor pulse 10. This inversion is particularly important for selective solid plate growth (2D).

Each cycle 1 makes it possible for the formation of a monolayer. If a plasma step 30 is started with, then the monolayer will be made at the end of 1.5 cycles.

It will be noted that the temperature T_{cycle} imposed on the substrate during cycles is less than the lower limit Tₘᵢₙ of the nominal temperature window F_{T}.

According to an advantageous example, the cycles are carried out at a temperature T_{cycle} such that T_{cycle}≤(Tₘᵢₙ- 20° C.), T_{cycle} being Tₘᵢₙ in degrees Celsius (°C). Preferably, T_{cycle} ≤ (Tₘᵢₙ - 50° C.). T_{cycle} can be greater than or equal to ambient temperature.

In this embodiment, it will also be noted that during the formation 32 of the plasma, a polarisation is applied to the substrate 100, usually called bias. In practice, the reaction chamber comprises a sample carrier to receive the structure 100. The sample carrier is electrically conductive and a polarisation voltage is applied to this sample carrier to be transmitted to the substrate 100 and as well as to its front face.

This polarisation voltage V_{bias}__{substrat} is applied to the substrate 100, for example via a voltage regulation device such as a radiofrequency power generator. The polarisation voltage V_{bias-substrat} can, for example, be strictly less than 0 (<0 V). A non-zero polarisation voltage V_{bias}__{substrat} can be positive or negative.

This polarisation voltage V_{bias-substrat} applied to the substrate is distinct from the potential of the plasma Vₚₗₐₛₘₐ. The polarisation voltage V_{bias} __{substrat}, is indeed distinguished from the potential of the plasma Vₚₗₐₛₘₐ which is induced, fully conventionally by the source of the plasma, in order to generate the ions and radicals and therefore initiate the dielectric deposition. The polarisation voltage V_{bias} __{substrat} is controlled independently from the potential of the plasma Vₚₗₐₛₘₐ induced by the source. The polarisation voltage V_{bias-substrat} is more specifically applied to a receiving plate of the substrate. “Applied to the substrate” means that the polarisation voltage V_{bias-substrat} is applied to the plate which supports the substrate 100, preferably which is in contact with the substrate 100, that the substrate 100 is conductive or not. In practice, like for example illustrated by FIG. 11, the reaction chamber 310 of the reactor 300, in this case an ICP reactor, comprises a receiving plate 320 of the substrate 100. This plate can also be qualified as a sample carrier. According to an example, the polarisation voltage V_{bias-substrat} is applied to the plate 320. Preferably, the polarisation voltage V_{bias-substrat} is applied only to the plate 320. According to this example, the plate 320 is electrically conductive and the polarisation voltage V_{bias-substrat} is applied to this plate 320 by a voltage regulation device 370 to be transmitted to the substrate 100.

The application of this polarisation voltage V_{bias-substrat}, provides considerable advantages. In particular, this polarisation makes it possible to modulate the energy of the ions from the plasma in a controlled manner, thanks to the regulation device 370. In a non-collisional sheath, the energy of the ions indeed depends on the potential of the plasma and on the polarisation voltage of the substrate, according to the following relationship.

$${E}_{i o n} = q \left({V}_{p l a s m a} - {V}_{b i a s - s u b s t r a t}\right) \qquad \text{[Math.1]}$$

With q the ion charge.

By applying a polarisation voltage V_{bias-substrat}, the effectiveness of the ionic bombardment on the surface can be increased, while preserving the exposed surface 101 of the substrate 100. Its repeatability is further improved with respect to current solutions, in particular those resorting to the potential of the plasma Vₚₗₐₛₘₐ induced by the plasma source to modulate the ionic bombardment which is, in practice, difficult to control to obtain a repeatable result.

The plasma and the polarisation V_{bias-substrat} are adjusted, so as to give a favoured direction to the flow 33 of the ions generated by the plasma. This favoured direction is oriented such that first surfaces 110 of the substrate 100 are exposed to the ion flow 33 and that the second surfaces 120 of the substrate 100 are not exposed to the ion flow 33.

In the non-limiting example of the substrate 100 in FIG. 6, the favoured direction of the ion flow 33 generated by the plasma being perpendicular to the rear face 102 of the substrate 100, thus:
the first surfaces 110 correspond to the horizontal surfaces, i.e. to the tops 111 and to the bottoms 112 of the trenches 101;
the second surfaces 120 correspond to the vertical surfaces, i.e. to the sides 112 of the trenches 101.

The polarisation voltage V_{bias} _{substrat} applied is less than 300 Volts, preferably less than 150 Volts. Usually, this polarisation is controlled by the adjustment of its power. This polarisation is therefore usually expressed in Watts (W). In the scope of the invention, this polarisation power P_{bias}__{substrat} is preferably less than 150 W, preferably less than or equal to preferably 100 W in absolute value (|V_{bias-substrat}|). Beyond this value, there is a risk of spraying the exposed surfaces or of implanting ions in the exposed surface.

FIG. 11 illustrates a diagram of a plasma reactor 300 which can be used to implement the method. Preferably, the method is implemented in a PEALD deposition plasma reactor.

According to an example, the reactor 300 comprises a plasma source 360 remote with respect to the reaction chamber 310. Thus, the potential of the Vₚₗₐₛₘₐ is remote from the substrate 100. The effect of the polarisation voltage V_{bias-substrat} increases the energy of the ions of the plasma at the substrate. In the absence of V_{bias-substrat}, for a zero voltage, the energy of the ions is equal to the product of the ion charge by the potential of the plasma Vₚₗₐₛₘₐ. The effectiveness of the ionic bombardment on the surface 101 can thus be best controlled that with respect to a non-remote source or a remote source which is not associated with the application of a polarisation voltage V_{bias-substrat}. For this, for example, this is provided by a second device for regulating the voltage of the substrate. The repeatability of the densification of the exposed face 101 is, consequently improved. Furthermore, the use of a remote source makes it possible to avoid any direct contact between the plasma in its formation zone and the substrate 100, which could damage the substrate. The use of a remote plasma source further minimises the directivity of the plasma treatment. The treatment of a three-dimensional structure, in particular of a nanostructure, is facilitated.

More specifically, the method is implemented in an inductive coupling plasma reactor, usually qualified by ICP (Inductively Coupled Plasma). Preferably, the source is a radiofrequency inductive source, which makes it possible to have a stable plasma at a power Pₚₗₐₛₘₐ less with respect to other sources, for example a microwave source. According to an example, the power Pₚₗₐₛₘₐ of the inductive radiofrequency source is between 100 and 300 W, preferably 200 W. The greater the power of the inductive radiofrequency source is, the more the ion flow which could reach the substrate 100 increases.

The reactor 300 comprises a reaction chamber 310 inside which a plate 320 is disposed. This plate 320 is configured to receive the substrate comprising the structure 100. The substrate rests on the plate 320 by a rear surface. The front face 101 of the structure 100 is exposed to the species present in the reaction chamber 310. In this non-limiting example, the substrate forms the structure 100 supporting the first surfaces 110 and the second surfaces 120 inclined against one another. The plate 320 is electrically conductive. Relatively conventionally, the reactor comprises a gas inlet 330, making it possible to inject inside the chamber 310, the gases intended to form the chemistry of the plasma, as well as the gases intended for the purging phases 20, 40. The plasma source 360 is, according to an example, an inductive coupling device, a coil of which is illustrated in FIG. 11, and which enables the formation of the plasma. The reactor 300 also comprises an insulation valve 340 of the reaction chamber 310. The reactor 300 also comprises a pump 350 to control the pressure inside the reaction chamber 310 synergically with the flow rate of the injected gases, and extract the species present in the reaction chamber 310.

Advantageously, this reactor 300 comprises a polarisation device 370 configured to enable the application of the polarisation voltage V_{bias-substrat} to the plate 320, for example via a radiofrequency power generator. This voltage can ultimately be applied to the substrate 100, at least at its rotated face, facing the plate 320, that this face is electrically conductive or not. This polarisation device 370 is preferably distinct from the plasma source 360. This polarisation device 370 comprises a control device 371 and makes it possible to apply an alternating voltage on the plate 320. Preferably, this control device 371 comprises an automatic adaptation unit (qualified by auto match unit) which adapts the impedance in the chamber and the ion source to that of the radiofrequency generator. This polarisation device 370 is configured to enable the application to the plate 320 of the polarisation voltage V_{bias-substrat}, the amplitude of which is low, typically such that the power P_{bias-substrat} is less than or equal to 150 Watts, and preferably between 10 and 120 W.

The polarisation device 370 and the plasma source 360 are configured to as to be able to adjust the polarisation voltage V_{bias-substrat} applied to the plate 320 independently from the potential of the plasma Vₚₗₐₛₘₐ. V_{bias-substrat} and Vₚₗₐₛₘₐ are independent. V_{bias-substrat} and Vₚₗₐₛₘₐ are controlled independently.

The power Pₚₗₐₛₘₐ of the inductive radiofrequency source is between 100 and 300 W, preferably 200 W. With an ICP reactor, it is not possible and is very difficult to obtain a plasma with a power Pₚₗₐₛₘₐ less than 100 W. Conversely, P_{bias-substrat} can fully be less than 100 Watts.

Therefore, it can be clearly seen that the powers P_{bias-substrat} and Pₚₗₐₛₘₐ have different functions and amplitudes which can therefore be different.

According to an example, P_{bias-substrat} < Pₚₗₐₛₘₐ. According to an example, P_{bias-substrat} < 0.8*Pₚₗₐₛₘₐ. According to an example, P_{bias-substrat} < 0.65*Pₚₗₐₛₘₐ.

The combination of these two parameters (T_{cycle} and polarisation V_{bias}__{substrat}) confers considerable advantages, which are presented below.

When the temperature of the method is adjusted below the minimum temperature of the PEALD window, the condensation (physisorption) processes are responsible for the growth. With these processes not being self-limited, the resulting deposition shows that the material formed has a deteriorated density and the inclusion of a significant quantity of carbon contaminations coming from the poor breakdown of the precursor 1, due to an activation temperature (at the substrate) which is too low.

The application of an additional radiofrequency (RF) polarisation V_{bias} __{substrat} at the sample carrier during the injection step of the precursor 2 with formation of the plasma enables the extraction of ions from the plasma to bring them perpendicularly to the vicinity of the film undergoing growth. This ion flow 33 of which the incident energy can be modulated by the amplitude of the polarisation of the substrate 100 makes it possible to benefit from the synergy that it creates during the deposition with the radicals of the plasma. Only the surfaces exposed to the energetic ion flow extracted from the plasma by the polarisation of the substrate 100 (the horizontal surfaces 110 on the non-limiting example of FIG. 6) can benefit from the effects induced by these ions during the PEALD growth. These effects are characterised by the fact that, by synergy mechanisms between the activated radicals and the ions of the plasma, the physiochemical properties of the thin layers developed by PEALD enhanced by RF polarisation of the substrate are modified. Indeed, a significant improvement of the chemical purity, of the stoichiometry and of the density of the material of this film deposited by PEALD is observed in the film exposed to the ion flow 33, which can be accompanied by a micro-crystallisation or a morphologic modification, as well as an improved deposition rate.

Thus, when a PEALD method is combined with T_{cycle} < Tₘᵢₙ under ionic bombardment, only the surfaces exposed to the ion flow (in this case, the horizontal surfaces 110) are covered by a good quality thin layer (purity, stoichiometry, density improved by the ionic bombardment), while the surfaces not exposed to the ion flow (in this case, the vertical surfaces 120) are covered with the same material, but of less good quality.

FIG. 6 schematically illustrates the result obtained under these operating conditions. The layer 200 thus comprises:
first regions 210 (211 on the tops and 212 in the bottom of the trenches 101) which have a good quality and
second regions 220 (on the sides 112 of the trenches 101) which have a lesser quality.

In particular, this lesser quality is manifested by a lesser density of the material in these second regions 220. This lesser quality is also manifested by a defect rate and/or a greater impurity rate in these second regions 220.

In this embodiment, the polarisation (V_{bias}__{substrat} ≠0) is applied during the formation step of the plasma 32 of each PEALD cycle. Thus, the plasma 32 has both the role of reactivating the ligands of the precursor 1 to make them reactive vis-a-vis the precursor 1 and the role of densifying the layer in the course of its formation selectively only on certain regions.

It results from this that the plasma under polarisation provides its advantageous effect over the whole thickness of the layer 200 formed by PEALD. Thus, the regions 210, 211, 212 exposed to the ion flow 33 are made denser over the whole thickness. Thus, as illustrated in FIG. 6, the thickness e₂₁₁ made dense in the regions 211 of the layer 200 covering the horizontal surfaces 111 is equal to the total thickness e₂₀₀ of the layer 200. Conversely, in the regions 220 of the layer 200 covering the vertical surfaces 120, the thickness of the layer made dense is zero.

The method further comprises a selective etching step, referenced 50 in FIG. 5, which is configured to selectively remove the low quality second regions 220 vis-a-vis the high quality first regions 210. This selectivity of the etching benefits from the lower density of the material and/or from its greater impurity rate of the regions 220 not exposed to the ion flow 33 of the plasma under polarisation.

The etching 50 can be carried out wet or dry. The selectivity to the etching is of at least a factor 2.

Thus, the desired structure is obtained as illustrated in FIG. 1B. This selective deposition according to the orientation of the surfaces 110, 120 of the substrate with respect to the ion flow 33 makes it possible to move from the usual lithography steps which are time-consuming and generate numerous inaccuracies.

### Particular Example of an Embodiment

The following paragraphs describe a non-limiting example of the present invention. This example is applied particularly well to the embodiment described in reference to FIGS. 5 and 6, wherein the deposition plasma also plays the role of densification plasma. However, the features proposed below are applicable and combinable to each of the embodiments described above and below.

The example given below relates to a deposition of Ta₂O₅ of 10 nm . However, this method and the features mentioned below, can be applied to thicknesses of a few nanometres to a few tens of nanometres (3 to 100 nm) and to any type of materials deposited by PEALD (oxides, nitrides and sulfides).

### 1. Formation Sequence of the Layer by PEALD:

To form the Ta₂O₅ layer by PEALD, a plurality of cycles 1 is carried out, such as that illustrated in FIG. 5 and described above. The following conditions can be applied during this sequence of cycles.
Precursor: To form a Ta₂O₅ layer, the precursor used, typically that injected during the step 10 is TBTDMT, i.e. Tris(dimethylamine)tert-Butylamino)tantalum Ta(N(C₄H₉))(N(CH₃)₂)₃.
Deposition temperature: The deposition temperature T_{cycle}, i.e. the temperature of the structure 100, is equal to 100° C. This temperature is less than 100° C. to the limit temperature Tₘᵢₙ less than the PEALD temperature window F_{T} for this precursor. It is preferable to deviate from this lower temperature by at least one hundred degrees, so as to significantly deteriorate the quality of the deposition without ion enhancement, which increases the selectivity of the subsequent etching step. In this way, the subsequent removal of this material by wet or plasma etching is facilitated, due to the high rate of carbon impurities present in the deposition and linked to the incomplete breakdown of the metalorganic precursor (precursor 1) traditionally used for PEALD methods. Temperatures T_{cycle} of strictly less than 100° C. can be resorted to. For example, T_{cycle} can be less than or equal to 80° C., and preferably less than or equal to 50° C.

According to an example, T_{cycle} is equal to ambient temperature. This means that the reactor wherein the steps of the method are implemented cannot be heated by heating means.
Energy of the RF polarisation at the substrate: The power P_{bias-substrat} of the RF polarisation applied to the substrate must be optimised to induce an effective synergy between the ions and the radicals of the plasma, i.e. leading to the densification of the deposition and the removal of the carbon impurities. However, it must be ensured that this power is not too high, in order to avoid the appearance of defects induced by the bombardment by ions coming from the plasma, such as surface roughening, spraying or implantation of the exposed surface. For this, a low RF power P_{bias} is recommended, typically 10 W ≤Pbias≤ 120 W.

The deposition rate, at 100° C., is 0.115 nm/cycle. The number of cycles is adjusted to achieve the desired thickness coming from this sequence of cycles 1. Typically, coming from this sequence, the layer has a thickness e₂₀₀ varying by a few nanometres to a few tens of nanometres.

### 2. Removal of Less Dense Regions of the Layer Deposited by PECVD:

After having formed the layer 200 by PEALD, by selectively defining in this layer 200, on the one hand, good quality regions 210 (high density, low impurity rate) covering certain surfaces 110, and on the other hand, degraded quality regions 220 (low density, high impurity rate) covering other surfaces 120, the selective etching step 50 is proceeded with.

Due to the use of PEALD metalorganic precursors, the impurities present in the layer deposited on the surfaces 120 not exposed to the ion flow 33 are very mainly of carbon origin. In addition, the deposition being very slightly dense here, preferably a selective wet removal of this layer will be used. For example, a 1 % to 5% (preferably 5%) diluted HF solution is shown fully selective between a dense metal oxide and the same very slightly dense oxide and containing carbon impurities.

For example, a dip in 5% HF of a duration of 50 seconds makes it possible to remove 10 nm of non-densified Ta₂O₅ developed in PEALD at 100° C., without etching the densified Ta₂O₅ layer by exposure to the ion flow.

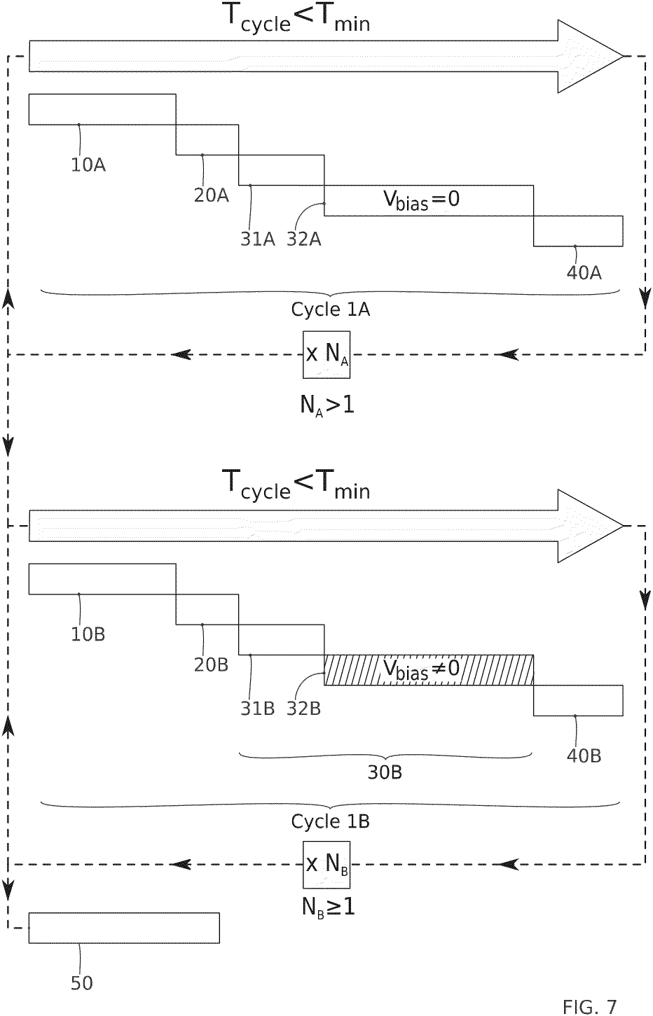

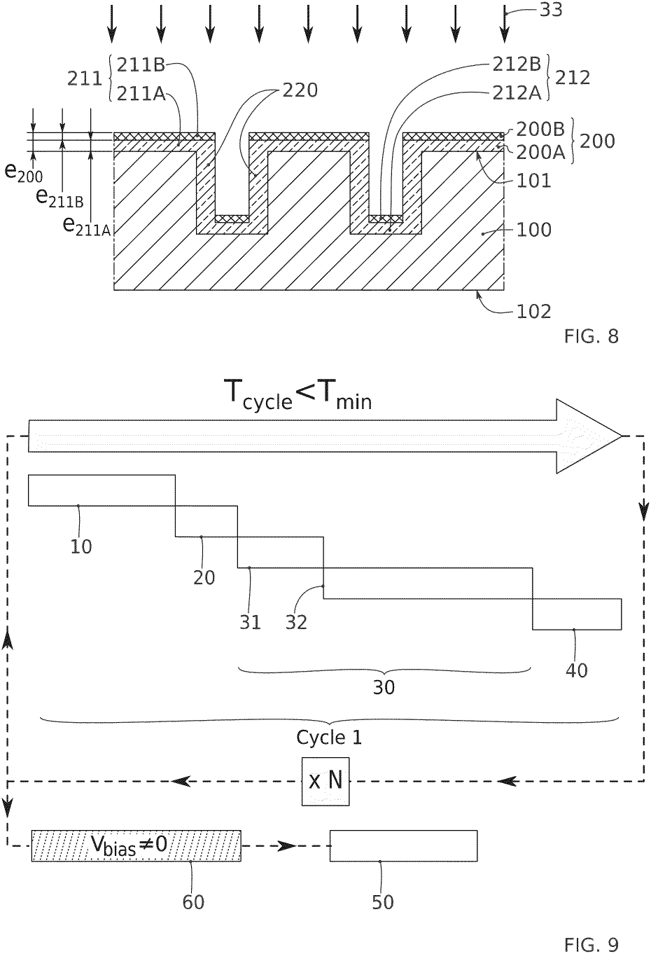

### Embodiment Illustrated in FIGS. 7 and 8

A second example of a method according to the invention will now be described in reference to FIGS. 7 and 8. FIG. 7 illustrates, schematically, the main steps of this embodiment. This method differs from the preceding embodiment by the fact that the polarisation of the substrate is applied only during the last cycle(s).

In more detail, the formation sequence of the layer 200 by PEALD comprises:
a first set of cycles, referenced 1A. These cycles 1A are identical to the PEALD cycle, illustrated in FIG. 5, almost except for no polarisation of the substrate is applied during the plasma 32A. At the very least, no polarisation of the substrate is applied during this plasma 32A with an adjustment making it possible to generate an ion flow 33 which selectively bombards the exposed surfaces 110 without bombarding the unexposed surfaces 120. During these cycles 1A, the deposition temperature T_{cycle} is less than the lower limit Tₘᵢₙ of the nominal window F_{T}, as in the embodiment illustrated in FIGS. 5 and 6. This first set of cycles 1A leads to the formation of a portion 200A of layer 200. As illustrated in FIG. 8, the portion 200A extends from the structure 100, preferably from its front face 101. It preferably covers the whole structure 100. It is conform. It has a constant thickness, identical on all the surfaces 110, 120 of the structure 100. This layer 200A has a degraded quality due to the low temperature T_{cycle} and to the absence of exposure to an ion flow 33.
a second set of cycles, referenced 1B. These cycles 1B are identical to the PEALD cycle, illustrated in FIG. 5. A polarisation V_{bias}__{substrat} is applied during the plasma 32B with an adjustment making it possible to generate an ion flow 33 which selectively bombards the exposed surfaces 110 without bombarding the unexposed surfaces 120.

During these cycles 1B also, the deposition temperature T_{cycle} is less than the lower limit Tₘᵢₙ of the nominal window F_{T}, like in the embodiment illustrated in FIGS. 5 and 6. As illustrated in FIG. 8, the layer 200 obtained in the end has;
in the regions which have been exposed to the ion flow 33 (in this case, regions which extend perpendicularly to the flow 33): portions 211B and 212B which thus have a very good quality. These portions 211B and 212B surmount the portions 211A, 212A formed during the cycle 1A which themselves have a degraded quality. Thus, in these horizontal regions 211, 212, the thickness e₂₀₀ of the layer is equal to the sum of the thickness e_{211A} of the portions 211A and the thickness e_{211B} of the portions 211B.
in the regions 220 which have not been exposed to the ion flow 33 (in this case, regions which extend parallel to the flow 33). These regions 220 have a degraded quality. These regions 220 have been formed by successive depositions of cycles 1A and 1B.

During the selective etching step 50, the whole thickness of the regions 220 of the layer 200 are etched. However, in the regions 211, 212, the superficial portions 211B, 212B resist etching and also protect the portions 211A and 212A which are subjacent to them. During the selective etching step 50, the layer 211A being consumed is avoided, which would lead to the removal of the layer 211B by lift-off. To this end, a dry etching can be favoured for the step 50.

Thus, in this embodiment, during the last N_{B} cycles for forming the initial layer 200 by PEALD, the plasma 32B has the role of densifying the deposited layer, in addition to participating in the PEALD deposition of this layer. The plasma 32B can thus be qualified as densification plasma and as deposition plasma. On the contrary, during the first N_{A} cycles, the plasma steps 32A do not have the role of densifying the deposited layer. The plasma 32A can thus be qualified as deposition plasma, but not densification plasma. If the total number of cycles is equal to N_{A}+N_{B}, N_{A} and N_{B} being non-zero integers, preferably, N_{B} ≤ 10 and preferably N_{B} ≤ 3, preferably N_{B} ₌ 1.

Naturally, the cycles 1A and 1B are preferably carried out in the same reactor. Preferably, the cycle 1B is carried out directly after the cycle 1A, preferably in the continuity of the cycle 1A, with as its only change, the application of the polarisation.

According to an embodiment, the method comprises an alternance of deposition cycles 1A without polarisation V_{bias}__{substrat} of deposition cycles 1B with polarisation V_{bias}__{substrat}. Preferably, for each sequence, the number N_{B} of deposition cycles with polarisation is equal to 1.

### Embodiment Illustrated in FIG. 9

A third example of a method according to the invention will now be described in reference to FIG. 9. FIG. 9 illustrates, schematically, the main steps of this embodiment. This method differs from that of the embodiment illustrated in FIGS. 5 and 6, mainly by the fact that the selective densification of the layer 200 is achieve only coming from the PEALD cycles.

More specifically:
during each of the PEALD cycles 1, the plasma 32 is formed without applying polarisation (V_{bias}__{substrat} = 0). The plasma 32 can thus be qualified as deposition plasma. This plasma does not make it possible to densify the deposited layer 200. This deposited layer therefore has a degraded quality, due to the deposition temperature T_{cycle} taken below the nominal window F_{T}.
coming from the PEALD cycles 1, the surface of the deposited layer 200 is exposed to an ionic bombardment generated by a plasma 60. A polarisation is applied to this plasma 60, so as to generate an ion flow in a favoured direction. This favoured direction makes it possible to expose certain regions 210, 211, 212 of the layer to an ionic bombardment without this ionic bombardment reaching the surfaces 220. This exposure using a plasma 60 with polarisation makes it possible to densify the exposed regions. This plasma 60 can thus be qualified as densification plasma.

According to an embodiment, this densification plasma 60 can be achieved in one single exposure.

Thus, only the superficial portion of the surfaces exposed to the flow 33 is densified. This superficial portion thus protects the layer 200 in the regions 210, 211, 212 only and leaves the other regions 220 of the layer 200 uncovered. This superficial portion suffices to prevent the etching of the regions 210, 211, 212. The unprotected regions 220 are themselves removed during etching.

The densification plasma 60 can be a, for example, argon (Ar)-, dioxygen (O₂)- or dinitrogen (N₂)-based plasma.

The densification plasma step 60 is preferably carried out at a low pressure for an anisotropic densification. Preferably, the pressure is less than 80 mTorr. According to a particularly advantageous example, this pressure is 10 mTorr. The polarisation power is between 10 W and 120 W, preferably between 10 W and 90 W, according to the preceding conditions, and the deposited material. This densification will preferably be done in situ, i.e. in the reactor having served the PEALD cycles 1. Preferably, this densification step is carried out immediately after the PEALD sequence. Alternatively, this plasma densification step can also be carried out ex-situ, i.e. after having removed the structure 100 from the reactor having served the PEALD sequence.

With respect to the preceding embodiments, this embodiment has the advantage of not damaging the substrate 100 by ionic bombardment. This route can also facilitate the adhesion of the material deposited on the substrate, due to the low quantity of precursor adsorbed in the first cycles, leading to the low density of the material.

Furthermore, this embodiment has the advantage of being able to be implemented in a reactor other than that having served the PEALD deposition cycles 1A without polarisation. This embodiment can therefore be implemented when the PEALD reactor does not enable the application of a polarisation. This embodiment therefore imposes less constraints on the necessary equipment.

The invention is not limited is not limited to the embodiments described above and extends to all the embodiments covered by the claims.

The paragraphs below aim to describe variants. The features of the variants proposed below and combinable with each of the examples mentioned above.

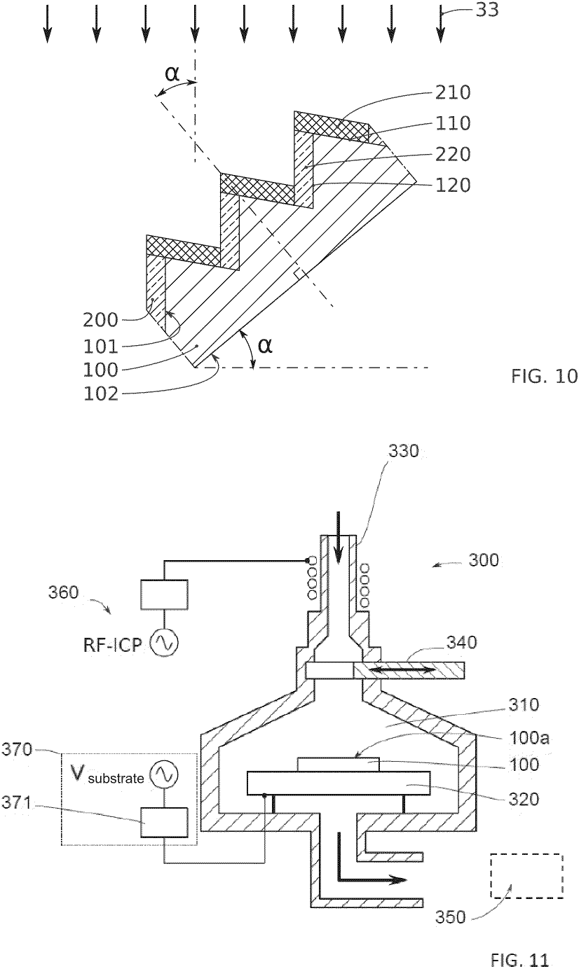

In the embodiments described above, the surfaces exposed to the plasma with polarisation (densification plasma) are horizontal and perpendicular to the favoured direction of the ion flow 33. However, it can be fully provided that the angle between the favoured direction of the ion flow 33 and the exposed surfaces are not a 90-degree angle. Such is, for example, the case of the embodiment illustrated in FIG. 10. In this figure, the structure 100 is inclined by an angle α with respect to the horizontal direction. This angle can be obtained by inclining the sample carrier of the structure 100. As appears in this FIG. 10, it suffices that the shape of the raised parts of the structure 100, i.e. the dimension and the inclinations of the surfaces 110, 120 as well as the direction of the ion flow 33 make it possible:
for the first surfaces 110 to be reached by the ion flow,
for the second surfaces 120 to not be reached by the ion flow. These second surfaces 120 can, for example, be shaded by the first surfaces 110.

Thus, the invention fully makes it possible to selectively deposit a layer 200 on the first surfaces 110 by leaving the second surfaces 120 free, which do not form a right angle with the first surfaces 110.

The first surfaces 110 of the structure 100, i.e. those which are facing the ion flow during the densification plasma can have the same inclination, as illustrated in FIGS. 6 and 8. The invention however extends to a structure 100, wherein the first surfaces 110 have at least two different inclinations. For example, certain first surfaces 110 form an angle φ1 with the rear face 102 of the structure 100 and other first surfaces 110 form an angle φ2 with this same rear 102. Likewise, the second surfaces 120 can also have at least two inclinations.

The first surfaces 110 and the second surfaces 120 of the structure 100, can be substantially flat as illustrated in FIGS. 6 and 8. The invention however extends to a structure 100, wherein these first 110 and/or these second 120 surfaces are not flat.

In the examples described above, the structure is a substrate 100, of which the structuring is formed by grooves 101 or trenches, of which the sides 120 form right angles with the tops 111 and the bottoms 112 of the grooves 101. All the examples, features, steps and technical advantages mentioned above are fully applicable and combinable with a substrate having other types of patterns. These can, for example, be grooves 101, of which the sides 120 do not form a right angle with the tops 111 and the bottoms 112 of the grooves 101. Moreover, these can be other shapes which can be very varied: terminals, holes, stepped patterns, etc.

Moreover, in the examples described above, the structuring of the substrate is distributed over the whole front face of the substrate. However, all the examples, features, steps and technical advantages mentioned above in reference to a structure forming a substrate are applicable to a structure not forming a substrate or a layer, but forming a punctual structure, for example a three-dimensional raised part. The structure can be a nanostructure or comprise a plurality of nanostructures.

Moreover, in the examples described above, the structuring of the substrate is supported by the substrate. This structuring can be fully supported or formed by a layer supported by the substrate.

1. A method for producing a layer covering first surfaces of a front face of a structure and leaving the second surfaces of this front face uncovered, the first surfaces and the second surfaces having different inclinations, the method comprising at least:
• one sequence of forming an initial layer by plasma-enhanced atomic layer deposition (PEALD) on the front face of the structure, the sequence comprising a plurality of cycles, each cycle comprising at least:
one injection of a first precursor in a reaction chamber of a reactor containing the structure,
one injection of a second precursor in the reaction chamber and the formation in the reaction chamber of a plasma, called deposition plasma, so as to form at each cycle, on said first and second surfaces of the structure, a film forming a portion of said initial layer, wherein:
the cycles are carried out at a temperature T_{cycle} such that T_{cycle}≤(Tₘᵢₙ - 20° C.), Tₘᵢₙ being the minimum temperature of a nominal temperature window (FT) for a PEALD deposition from the first and second precursors, the nominal window (FT) being such that by varying the PEALD deposition temperatures, by taking these PEALD deposition temperatures in the nominal window, the thickness of the film deposited at each PEALD cycle remains constant,
the method comprises at least one step of exposing the initial layer, formed or undergoing formation by PEALD, to a plasma, called densification plasma, during which a non-zero polarisation is applied to the structure so as to give a favoured direction to an ion flow generated by the densification plasm, this favoured direction being oriented such that at least one superficial portion of the initial layer, deposited or undergoing formation by PEALD, has:
o first regions, covering the first surfaces of the structure and which are exposed to the ion flow of the densification plasma,
o second regions, covering the second surfaces of the structure and which are not exposed to the ion flow of the densification plasma,
the densification plasma, at least the polarisation, being configured such that the exposure to the ion flow of the densification plasma makes the material of the first regions more resistant to etching than the material of the second regions,
the method also comprises, coming from the at least one step of exposing to the densification plasma of the initial layer, formed or undergoing formation by PEALD, at least one selective etching step of the second regions vis-à-vis the first regions such that after etching, the initial layer covers the first surfaces of the front face of the structure by leaving the second surfaces uncovered.

2. The method according to claim 1, wherein the step of exposing the initial layer to the densification plasma is carried out at each cycle of the sequence of forming the initial layer by PEALD, the deposition plasma being the densification plasma.

3. The method according to claim 1, wherein the at least one step of exposing the initial layer to the densification plasma is only carried out during the last NB cycles of the sequence of forming the initial layer by PEALD, during these last NB cycles, the deposition plasma being the densification plasma, the total number of cycles of the sequence being equal to NA+NB, NA and NB being non-zero integers.

4. The method according to claim 3, wherein NB =1.

5. The method according to claim 1, wherein the at least one step of exposing the initial layer to the densification plasma is carried out only after the sequence of forming the initial layer by PEALD.

6. The method according to claim 3, comprising a plurality of sequences, each sequence comprising NB steps of exposing the initial layer to the densification plasma, NB being a non-zero integer.

7. The method according to claim 1, wherein the cycles are carried out at a temperature T_{cycle} less than 100° C. .

8. The method according to claim 1, wherein the cycles are carried out at a temperature T_{cycle} equal to ambient temperature.

9. The method according to claim 1, wherein the cycles are carried out at a temperature T_{cycle} such that: T_{cycle}≤(Tmin - 50° C.).

10. The method according to claim 1, wherein T_{cycle}≤(Tmin - 100° C.).

11. The method according to claim 1, wherein a width L = Tₘₐₓ- Tₘᵢₙ of the nominal window FT is greater than or equal to 10° C.

12. The method according to claim 1, wherein a width L = Tₘₐₓ-Tₘᵢₙ of the nominal window FT is greater than or equal to 100° C. .

13. The method according to claim 1, wherein during the formation of the densification plasma, pressure is less than or equal to 80 mTorr.

14. The method according to claim 1, wherein the polarisation is applied with a polarisation power P_{bias} less than or equal to 150 Watts, .

15. The method according to claim 1, wherein the first regions exposed to the densification plasma and the second regions not exposed to the densification plasma differ by at least one of the following parameters: a density of the film or an impurity rate.

16. The method according to claim 1, wherein the initial layer is made or is nitride- or oxide-based, preferably obtained from metalorganic, organosilicon or halogenated precursors.

17. The method according to claim 1, wherein the initial layer is made or is sulfide-based.

18. The method according to claim 1, wherein the first precursor comprises one of the following materials: aluminium (Al), titanium (Ti), tantalum (Ta), silicon (Si), hafnium (Hf), zirconium (Zr), copper (Cu), ruthenium (Ru), lanthanum (La), yttrium (Y).

19. The method according to claim 1, wherein at least certain first and second surfaces together form a right angle.

20. The method according to claim 1, wherein at least certain first and second surfaces do not together form a right angle and wherein a rear face of the structure extends into a plane, a perpendicular to this plane being inclined with respect to the favoured direction of the ion flow.

21. The method according to claim 1, wherein the total number N of cycles of said sequence is greater than or equal to 15.
